(19) United States
(12) Patent Application Publication
(10) Pub. No.: US 2005/0083668 A1
(43) Pub. Date: Apr. 21, 2005

(54) Unlatching structure

(76) Inventor: Lin-Wei Chang, Taipei (TW)

Correspondence Address: RABIN & CHAMPAGNE, P.C., Suite 500, 1101 14 Street, N.W., Washington, DC, 20005, US

(21) Appl. No.: 10/684,433

(22) Filed: Oct. 15, 2003

(51) Int. Cl. H05K 7/14; H05K 7/18

(52) U.S. Cl. 361/801

(57) ABSTRACT

An unlatching structure adopted for used on interface cards to release the latching relationship between an interface card and a server case includes an elastic slice and a pulling lever. The elastic slice is located on one side of the interface card and juts out from the surface of the interface card for latching onto the server case. The pulling lever is pivotally engaged with the interface card corresponding to the elastic slice. Moving the pulling lever drives the elastic slice close to the surface of the interface to unlatch the elastic slice from the server case.

### FIELD OF THE INVENTION

The invention relates to an unlatching structure adopted for used on interface cards, and particularly to an unlatching structure for releasing the latching relationship between an interface card and a server case.

### BACKGROUND OF THE INVENTION

There are many ways to install interface cards in a server. In order to install an interface card securely in the server, the server usually has latch means to anchor the interface card.

One of the commonly used latching approaches is to form openings on the server case, and have elastic slices mounted on two opposite sides of the interface card that are jutting out from the surface thereof in normal conditions. Each of the elastic slices further has a latch section protruding from the surface thereof. By means of such a design, when the interface card is loaded into the server, the latch section of the jutting elastic slice is engaged with the opening of the server case to form a secured latching relationship between the interface card and the server.

Of course the interface card also has an unlatching design to release the latching relationship between the interface card and the server case. The common design is to inversely fold the elastic slice to create a force applying section. Users can directly exert force by hand on this section to release the latching relationship between the interface card and the server case. However, such an unlatching approach frequently hurts users' hands. Moreover, the force required for unlatching is difficult to control.

Another commonly used latch approach is to install the interface card in the server case, and fasten the interface card securely to the server case by screwing. Such an approach requires hand tools and is not convenient. During release of the latching relationship between the interface card and the server case, users' hands also are frequently hurt. Also, the force required for unlatching is difficult to control.

### SUMMARY OF THE INVENTION

The primary object of the invention is to provide an unlatching structure to facilitate release of the latching relationship between the interface card and server case without hurting users' hands.

The unlatching structure of the invention aims at releasing the latching relationship between the interface card and server case. The unlatching structure includes an elastic slice and a pulling lever. The elastic slice is located on one side of the interface card and juts outside the surface of the interface card in normal conditions for latching on the server case. The elastic slice has a driven section. The pulling lever is pivotally engaged with interface card corresponding to the driven section of the elastic section such that the pulling lever can drive and move the elastic slice close to the surface of the interface card without latching onto the server case.

The driven section may be an aperture. The pulling lever includes a bar type driving section corresponding to the aperture. When the pulling lever is pivotally turned, the driving section enters the aperture to drive and move the elastic slice close to the surface of the interface card without latching onto the server case.

In another embodiment, the driven section may be an inverse folding section formed on the elastic slice. The pulling lever has a distal end spaced from the pivotal location at a distance greater than the distance between the lower edge of the pulling lever and the pivotal location. Thus when the pulling lever is pivotally turned, the elastic slice is driven close to the surface of the interface card without latching onto the server case.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is an exploded view of a first embodiment of the invention with the interface card detached from the server case.

FIG. 2 is a perspective view of the first embodiment of the invention with the interface card latched on the server case.

FIG. 3 is an exploded view of the first embodiment of the invention.

FIGS. 4A, 4B and 4C are fragmentary schematic views of the first embodiment of the invention showing the interface card and the server case in various latching operations.

FIG. 5 is an exploded view of a second embodiment of the invention.

FIGS. 6A, 6B and 6C are fragmentary schematic views of the second embodiment of the invention showing the interface card and the server case in various latching operations.

### DESCRIPTION OF THE PREFERRED EMBODIMENTS

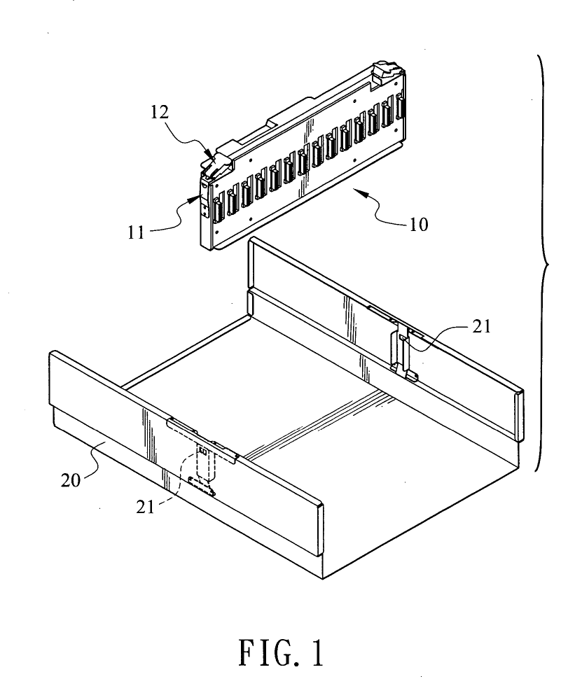

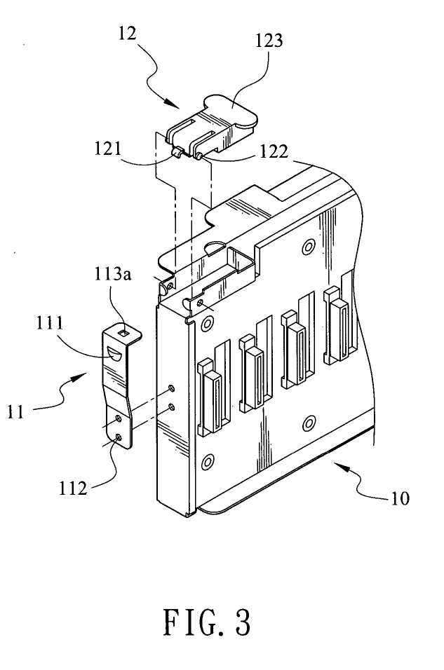

Refer to FIGS. 1, 2, and 3 for a first embodiment of the unlatching structure of the invention adopted for use on an interface card 10 to release the latching relationship between the interface card 10 and a server case 20.

The unlatching structure of the invention includes an elastic slice 11, a pulling lever 12 and an opening 21. The elastic slice 11 is located on one side of the interface card 10 and juts out from the surface of the interface card 10 in normal conditions for latching the interface card 10 on the server case 20. The elastic slice 11 includes a latch section 111, holes 112 and a driven section. The latch section 111 protrudes from the surface of the elastic slice 11 for latching the interface card 10 on the server case 20. The holes 112 enable fastening elements to pass through to fasten the elastic slice 11 to one side of the interface card 10. The driven section is an aperture 113a.

The pulling lever 12 is made from plastic. It is pivotally engaged with the interface card 10 corresponding to the driven section of the elastic slice 11. Thereby the pulling lever 12 may be moved to drive the driven section of the elastic slice 11 close to the surface of the interface card 10 without latching the server case 20. The pulling lever 12 includes a driving section 121, a pivot section 122 and a force applying section 123. The driving section 121 is a bar corresponding to the aperture 113a. When the pulling lever 12 is pivotally turned, the driving section 121 enters the aperture 113a and moves the elastic slice 11 close to the surface of the interface card 10 without latching the server case 20. The pivot section 122 is pivotally engaged with the interface card 10. The force applying section 123 may receive a force to allow the pulling lever 12 to turn pivotally.

The opening 21 is located on the server case 20 corresponding to the latch section 111.

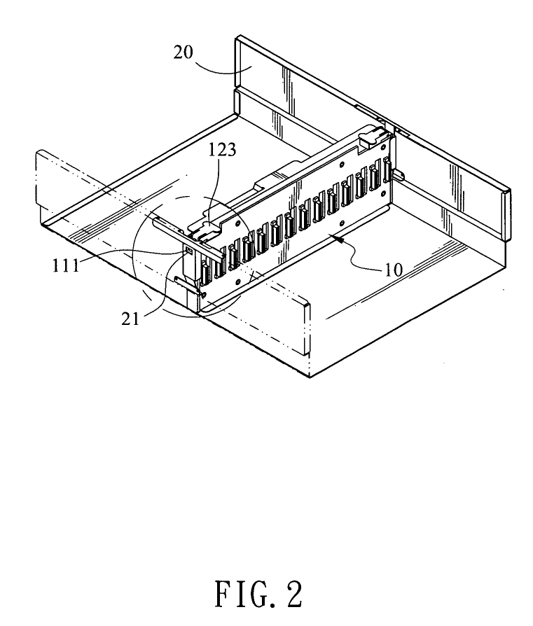

Therefore when the interface card 10 is inserted in the server case 20, because the elastic slice 11 juts from the surface of the interface card 10 in normal conditions, the latch section 111 is engaged with the opening 21 to latch the interface card 10 on the server case 20 (as shown in FIG. 2).

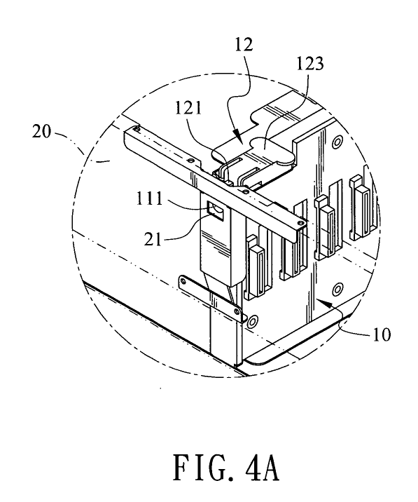

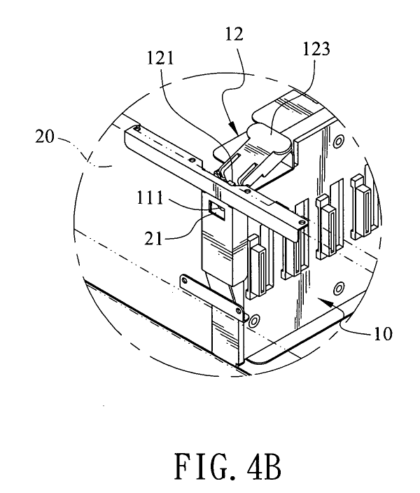

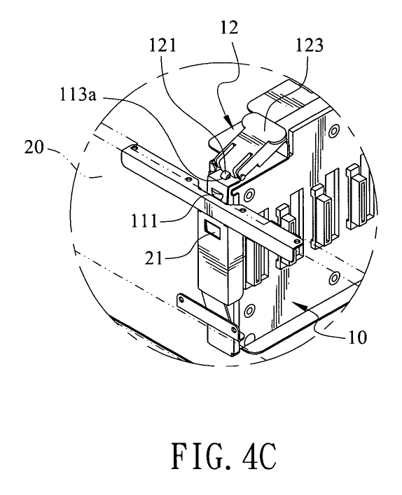

Referring to FIGS. 1, 2, 3 and 4A through 4C, to release the latching relationship between the interface card 10 and the server case 20, first, exert a force on the force applying section 123 to turn the pulling lever 12 pivotally about the pivot section 122. The driving section 121 enters the aperture 113a and moves the elastic slice 11 close to the surface of the interface card 10, and the elastic slice 11 is unlatched from the server case 20. Then the force applying section 123 may be moved upwards to release the latching relationship between the interface card 10 and the server case 20.

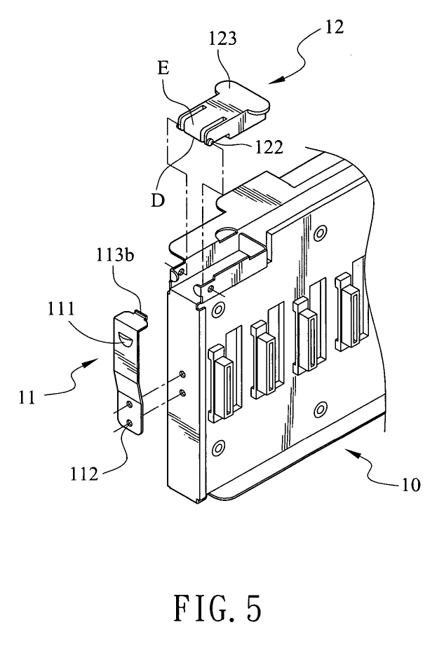

Refer to FIG. 5 for a second embodiment of the unlatching structure of the invention adopted for use on an interface card 10 to release the latching relationship between the interface card 10 and a server case 20 (also referring to FIGS. 1 and 2).

The unlatching structure of the invention includes an elastic slice 11, a pulling lever 12 and an opening 21. The elastic slice 11 is located on one side of the interface card 10 and juts out from the surface of the interface card 10 in normal conditions for latching the interface card 10 on the server case 20. The elastic slice 11 includes a latch section 111, holes 112 and a driven section. The latch section 111 protrudes from the surface of the elastic slice 11 for latching the interface card 10 on the server case 20. The holes 112 enable fastening elements to pass through to fasten the elastic slice 11 to one side of the interface card 10. The driven section is an inverse folding section 113b formed on one end of the elastic slice 11.

The pulling lever 12 is made from plastic. It is pivotally engaged with the interface card 10 corresponding to the driven section of the elastic slice 11. Thereby the pulling lever 12 may be moved to drive the driven section of the elastic slice 11 close to the surface of the interface card 10 without latching the server case 20. The pulling lever 12 includes a pivot section 122 and a force applying section 123. The pivot section 122 is pivotally engaged with the interface card 10. The force applying section 123 may receive a force to allow the pulling lever 12 to turn pivotally. The pulling lever 12 has a distal end E, which is spaced from the pivotal location at a distance greater than the distance between the lower edge D of the pulling lever 12 and the pivotal location (also referring to FIG. 5).

The opening 21 is located on the server case 20 corresponding to the latch section 111.

Therefore when the interface card 10 is inserted in the server case 20, because the elastic slice 11 juts out from the surface of the interface card 10 in normal conditions, the latch section 111 is engaged with the opening 21 to latch the interface card 10 on the server case 20 (as shown in FIG. 2).

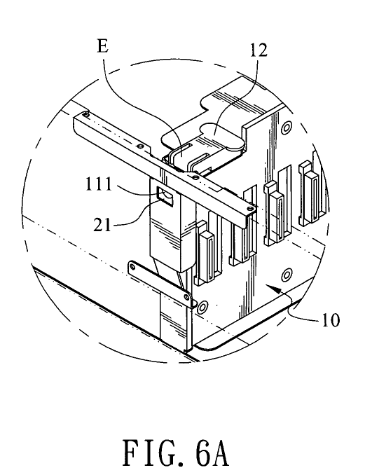

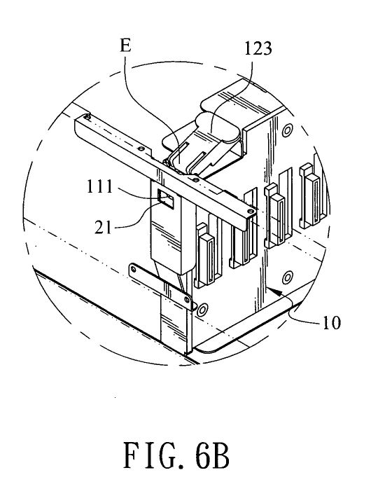

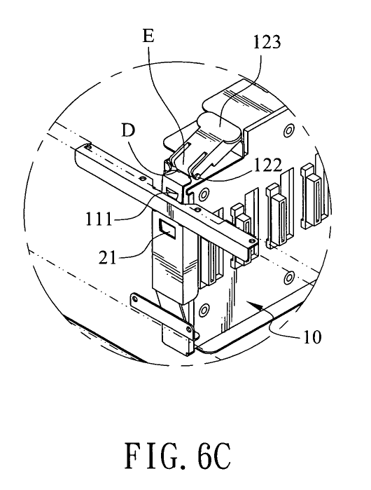

Referring to FIGS. 2, 5 and 6A through 6C, to release the latching relationship between the interface card 10 and the server case 20, first, exert a force on the force applying section 123 to turn the pulling lever 12 pivotally about the pivot section 122. The pivot section 122 drives the inverse folding section 113b and moves the elastic slice 11 close to the surface of the interface card 10, and the elastic slice 11 is unlatched from the server case 20. Then the force applying section 123 may be moved upwards to release the latching relationship between the interface card 10 and the server case 20.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

1. A unlatching structure used for an interface card to release latching relationship between the interface card and a server case, comprising:
an elastic slice, located on one side of the interface card, protruded from the surface of the interface card to latch the interface card on the server case; and
a pulling lever, pivotally engaged with the interface card, movable to drive the elastic slice close to the surface of the interface card to unlatch the elastic slice from the server case.

2. The unlatching structure of claim 1, wherein the server case has an opening, and the elastic slice has a latch section, protruded from the surface thereof, corresponding to the opening for latching the interface card on the server case.

3. The unlatching structure of claim 1, wherein the elastic slice has a hole to receive fastening elements to fasten the elastic slice to the one side of the interface card.

4. The unlatching structure of claim 1, wherein the elastic slice further has a driven section corresponding to the pivot location of the interface card such that moving of the pulling lever drives the elastic slice close to the surface of the interface card to unlatch the elastic slice from the server case.

5. The unlatching structure of claim 4, wherein the driven section is an aperture, and the pulling lever has a driving section corresponding to the aperture such that pivotal turning of the pulling lever moves the driving section to enter the aperture and drive the elastic slice close to the surface of the interface card to unlatch the elastic slice from the server case.

6. The unlatching structure of claim 5, wherein the driving section is a bar.

7. The unlatching structure of claim 4, wherein the driven section is an inverse folding section formed on the elastic slice, the pulling lever having a distal end spaced from the pivotal location at a distance greater than the distance between a lower edge of the pulling lever and the pivotal location such that pivotal turning of the pulling lever moves the elastic slice close to the surface of the interface card to unlatch the elastic slice from the server case.

8. The unlatching structure of claim 1, wherein the pulling lever further has a pivot section to pivotally engage with the interface card.

9. The unlatching structure of claim 1, wherein the pulling lever further has a force applying section for pivotally turning the pulling lever.

10. The unlatching structure of claim 1, wherein the pulling lever is made from plastics.
